(19) United States
(12) Patent Application Publication
(10) Pub. No.: US 2024/0186442 A1
(43) Pub. Date: Jun. 6, 2024

(54) GAMMA RAY DETECTOR STRUCTURE BASED ON P-I-N JUNCTION OF PEROVSKITE AND CALIBRATION METHOD

(71) Applicant: SUZHOU YIXIAN ELECTRONIC TECHNOLOGY CO., LTD., Suzhou, (CN)

(72) Inventors: Wei LEI, Nanjing (CN); Jianming ZHOU, Nanjing (CN); Ying ZHU, Nanjing (CN)

(73) Assignee: SUZHOU YIXIAN ELECTRONIC TECHNOLOGY CO., LTD., Suzhou (CN)

(21) Appl. No.: 18/026,350

(22) PCT Filed: Oct. 12, 2022
(86) PCT No.: PCT/CN2022/124737

§ 371 Date: Mar. 15, 2023

(30) Foreign Application Priority Data
Oct. 18, 2021 (CN) 202111208865.3

(51) Int. Cl. H01L 31/115; G01T 7/00; H01L 31/02; H01L 31/032

(52) U.S. Cl. CPC H01L 31/115; G01T 7/005; H01L 31/02019; H01L 31/032

(57) ABSTRACT

A γ ray detector structure based on a p-i-n junction of perovskite and a calibration method are provided. An ultrathick intrinsic perovskite crystal grows by utilizing temperature inversion solution crystallization as a γ ray photon absorber, a p-type perovskite epitaxial layer grows on one side of the intrinsic perovskite crystal by adopting an epitaxial doping growing method, a n-type perovskite epitaxial layer grows on the other side, a dark state current and noise are inhibited by utilizing the p-i-n junction of perovskite, and a large-sized perovskite crystal is used to absorb and convert more γ photons. Detected signals at a cathode terminal and an anode terminal are measured simultaneously. The longitudinal interaction depths of the γ photons are calibrated according to the ratio of the two signals, and then detection events at the same depth are classified and counted respectively.

### CROSS REFERENCE TO THE RELATED APPLICATIONS

This application is the national phase entry of International Application No. PCT/CN2022/124737, filed on Oct. 12, 2022, which is based upon and claims priority to Chinese Patent Application No. 202111208865.3, filed on Oct. 18, 2021, the entire contents of which are incorporated herein by reference.

### TECHNICAL FIELD

The present invention relates to the field of γ ray detection, and particularly relates to a γ ray detector structure based on a p-i-n junction of perovskite and a calibration method.

### BACKGROUND

γ ray detection with high sensitivity and high energy resolution has important applications in homeland security, industrial detection and medical images. Since 1950, the high purity semiconductors are often used as the active materials in the commercial γ ray spectral detector, such as high purity Ge(HPGe) and CdTe. An HPGe detector is capable of acquiring very high energy resolution, so that it is considered as a golden standard for radiation detection. However, as HPGe has a narrower band gap, it needs to work in a liquid nitrogen environment to suppress the thermal noise, which restricts its application. People have explored a semiconductor active material capable of working at room temperature and acquiring similar performance with HPGe all the time. However, the progress is still restricted. Only Cd₁₋ₓZnₓTe (x≈0.1, CdZnTe or CZT) has been commercialized, but its preparation cost is very high.

As γ photons feature high energy, to improve the detection efficiency of the γ photons, it needs to use a CZT detector with a large volume. However, after the volume of the detector increases, besides sudden rise of the preparation cost, the trapping and releasing of carriers induced by crystal defects of CZT severely affects the energy resolution of the detection energy spectrum. In order to solve the problem, people have proposed a pixilated CZT detector structure, as shown in FIGS. 1A-1C.

In the pixilated CZT detector structure, anodes are arranged as arrayed pixilated anodes (1). Through an insulating ring belt (3), a common grid (2) is arranged out of the array of the pixilated anodes (1), and cathodes are arranged as planar cathodes (4). The detector structure can substantially determine the position where the γ photons interact with the detector through the arrayed pixilated anodes (1) and planar cathodes (4) to calibrate the obtained energy spectrum of the γ ray, so as to obtain a higher energy resolution. According to reports, the half peak full width (FWHM) to the energy spectrum of the 662 keV γ ray photons is 1.1% ((7.3 keV). However, in the pixilated detector structure, each pixilated anode (1) needs to collect a detection signal by using a sensitive charge amplifier. Therefore, the system cost is increased, and moreover, electronic noise of a reading circuit is also increased.

As the number of photo-induced electron-hole pairs generated by a single γ photon is relatively small, they are likely to be trapped and recombined due to defects of a material and effects of impurities. Therefore, either the HPGe detector or the CZT detector requires the detection active material to have very high intrinsic purity (at least reaching 12 N and 7N). Thus, the probability of carriers recombination by traps can be reduced as much as possible, so that photo-induced carriers have enough collection efficiency. Halide perovskite APbX₃ is a novel semiconductor material. Although its degree of purity is relatively low (the degree of purity of CsPbBr₃ is about 5N), the carrier transportation still has very good performance due to better tolerability of perovskite crystals to parasitic defect. Early stage studies have indicated that (MA, FA)PbX₃ perovskite has a very good detector application prospect.

A research group of Northwestern University has reported a high resolution γ ray energy spectrometer based on a perovskite crystal. Its structure is shown in FIGS. 2A and 2B. In the detector structure, in order to improve the transmission performance of the photo-induced carriers, the detector structure uses PTAA and C₆₀ as a hole transmission layer (10) and an electron transmission layer (8), respectively. The perovskite crystal is used as an absorption and conversion layer of the γ photons. Similar to the structure in FIGS. 1A-1C, the detector structure also uses the coplanar cathodes (7) and the pixilated anodes (11). According to reports, by using the detector with the volume of 6.65 mm³, 1.4% of energy resolution is obtained to 662 keV γ ray. However, the detector structure uses organic materials as the electron transmission layer and the hole transmission layer. These functional layers are aged in performance quickly under high energy γ ray radiation to generate extra noise. In addition, heterojunction interfaces formed by these organic functional layers and the perovskite crystal have many defects and will also generate additional noise, so that the detection energy resolution is reduced.

### SUMMARY

The objective of the present invention is to provide a γ ray detector structure based on a p-i-n junction of perovskite and a calibration method, so as to solve the above technical problems.

In order to solve the technical problems, the present invention adopts the following technical solution: a γ ray detector structure based on a p-i-n junction of perovskite, including the following parts:
Part I: an ultrathick intrinsic perovskite crystal (for example, an MAPbBr_{2.5}Cl_{0.5} perovskite crystal with thickness greater than 1 cm) is used as a γ ray photon absorber, and relatively high γ ray photon absorptive conversion efficiency is obtained by utilizing a high absorption coefficient of the perovskite crystal; and a dark current of a detector is reduced by utilizing high resistivity of the intrinsic perovskite crystal;
Part II: a p-type layer of perovskite grows epitaxially through solution doping on an upper end surface of a photon absorption layer of the intrinsic perovskite crystal, wherein the p-type layer and the intrinsic layer have matched lattice structures, with low interface defect density and excellent hole transportation performance;
Part III: an n-type layer of perovskite grows epitaxially through solution doping on a lower end surface of a photon absorption layer of the intrinsic perovskite crystal, wherein the n-type layer and the intrinsic layer have matched lattice structures, with low interface defect density and excellent electron transportation performance; and
Part IV: metal electrodes are deposited on the end surfaces of the p-type layer and the n-type layer, respectively, the metal electrodes and the perovskite functional layer have the ohmic contact characteristic, a p-type electrode is grounded, a positive voltage is applied to the n-type electrode, the depletion layer of the p-i-n junction of perovskite is widened through the bias voltage setting, and injection of the dark carriers is inhibited and external noise is prevented from entering the detector by utilizing the depletion layer.

Preferably, a p-type epitaxial layer of the perovskite crystal is arranged at the upper end of the perovskite intrinsic crystal thicker than 1 cm, an anode electrode is arranged at the upper end of the p-type epitaxial layer, an n-type epitaxial layer of the perovskite crystal is arranged at the lower end of the perovskite intrinsic crystal, a cathode electrode is arranged at the lower end of the n-type epitaxial layer, and sensitive load amplifiers are arranged at an anode terminal and a cathode terminal respectively to form a perovskite detector.

Preferably, the pulse time width of a reverse bias pulse voltage applied by the perovskite detector is smaller than d/(μE), wherein d is the thickness of the perovskite intrinsic crystal, μ is the carrier mobility, and E is the average electric field intensity. The period of the pulse voltage is longer than the service life τ of carriers.

By utilizing the above p-i-n junction detector structure of perovskite, the present invention further provides a calibration method for a γ ray detector structure based on a p-i-n junction of perovskite, including the following steps:
1) measuring detected signals at an anode terminal and a cathode terminal simultaneously, and calibrating the longitudinal interaction depths of the γ photons according to the ratio of the two signals;
2) classifying and counting detection events at the same depth respectively, and determining calibration parameters by utilizing known characteristic peaks; and
3) obtaining a total detection energy spectrum curve according to a photon energy superposition method.

As shown in FIG. 3, when the geometric dimension of a photon conversion active body is relatively large, the photons emitted from the γ ray source may be incident into a detector absorber at different angles. Assuming that the γ ray is incident at two angles (12) and (13) herein, they are absorbed in two spatial positions (14) and (15), respectively and generate electron-hole pairs. As the incident angles of the γ rays (12) and (13) are different, the depth positions of the electron-hole pairs (14) and (15) are different. As shown in FIG. 3, Lₕ₁>Lₕ₂, Lₑ₁<Lₑ₂. In conventional photon counting detection, the cathode (18) is grounded and the potential is zero. A negative bias voltage is applied to the cathode (16) to form reverse bias setting. Subjected to an externally applied electric field, the electron-hole pairs generated by the γ ray are separated. The holes with positive charges drift towards the anode (16) and the electrons with negative charges drifts towards the cathode (18). Usually, a sensitive charge amplifier (19) is arranged on an anode loop. Energy of the γ photons is determined by detecting the amplitude 1a of the anode current and setting different channel threshold values. In γ ray detection, the thickness of the photon absorber (17) is usually much larger than the drift length μτE of the carrier, wherein p is the carrier mobility, ti is the service life of the carrier, and E is the average electric field intensity. Therefore, a part of photo-induced carriers may be recombined before being collected by the electrode. The anode current Id is in reverse proportion to the incident depth Lₕ substantially. In FIG. 3, as the incident depths of the electron-hole pairs (14) and (15) are different, there may be a certain difference in the spectral line peak channel number obtained by the photon counting detection, and a typical spectral line is as shown in FIG. 4.

It can be seen from the detection spectral lines shown in FIG. 4 that when the incident depths of the γ ray are Lₕ₂ and Lₕ₁, two detection spectral lines (20) and (21) are formed respectively. The energy channel numbers corresponding to the peak energy of the spectral lines (20) and (21) are (23) and (24) respectively. As the incident depths of the γ ray are different, the two energy channel numbers are not superposed. In addition, as Lₕ₂ and Lₕ₁ are not identical, the counting peak values of the detection spectral lines (20) and (21) are different, too. The peak value of the detection spectral line (21) is slightly lower than that of the detection spectral line (20).

In a conventional detection method, the detection current is recorded by the sensitive charge amplifier (19). A general detection result is to overlap the detection signals generated at different incident depths of the γ ray, i.e., to overlap the detection spectral lines (20) and (21), which are represented as the detection spectral line (22) in FIG. 4. In the detection spectral line (22), the channel number corresponding to the peak energy is (25), and the width (FWHM) of the spectral line is (26). It can be seen that as the detection spectral lines (20) and (21) are overlapped, the width of the general detection spectral line (22) increases, indicating that overlapping of the detection signals formed at different incident depths of the γ ray results in a poor energy resolution of the detector.

In order to solve the above problems, the present invention provides an improved detector structure and an incident depth calibration algorithm, as shown in FIG. 5. Compared with the detector structure shown in FIG. 3, a sensitive charge amplifier (27) is additionally arranged at the cathode terminal of the detector structure, which can measure the current Ic at the cathode terminal. The current Ic at the cathode terminal is not only in reverse proportion to the incident depth Lₕ, but also in direct proportion to the energy E of γ photons. Based on the premise that the energy information of the γ photons is unknown, the incident depth Lₕ of the γ photons cannot be completely determined by only measuring the anode current Ia. In the detector structure shown in FIG. 5, we further measure the cathode current Ic. As Ia and Ic are measured at the same time, the current ratio Ia/Ic is irrelevant to the energy of the incident γ photons, which is only in direction proportion to Lₑ/Lₕ. When the anode (16) and the cathode (18) in the structure shown in FIG. 5 both are planar structures, the ratio Lₑ/Lₕ can represent the incident depth of the γ photons.

In accordance with the above principle, the test method provided by the present invention includes:

S1: acquiring an anode terminal count value Count_a(i) and a cathode terminal count value Count_c(i) of each energy channel I by way of photon counting, wherein I is the energy channel number, and further recording depth position information (Lₑ/Lₕ)j when each γ photon interaction event occurs, wherein j is the interaction event number.

S2: setting m levels for the depth position information (Lₑ/Lₕ), and dividing the interaction event count values obtained in the previous step into m sub-sets according to a proximity principle of the depth position information (Lₑ/Lₕ), which are respectively anode terminal count [Count_a(1), Count_a(2), . . . , Count_a(i), . . . , Count_a(n−1), Count_a(n)]1, . . . ,

[Count_a(1), Count_a(2), . . . , Count_a(i), . . . , Count_a(n−1), Count_a(n)]j, . . . , [Count_a(1), Count_a(2), . . . , Count_a(i), . . . , Count_a(n−1), Count_a(n)]m, wherein i is the energy channel number, the maximum energy channel number is n, j is the depth position level number and the maximum level number is m, and similarly, acquiring the cathode terminal count [Count_c(1), Count_c(2), . . . , Count_c(i), . . . , Count_c(n−1), Count_c(n)]1, . . . ,

[Count_c(1), Count_c(2), . . . , Count_c(i), . . . , Count_c(n−1), Count_c(n)]j, . . . , [Count_c(1), Count_c(2), . . . , Count_c(i), . . . , Count_c(n−1), Count_c(n)]m.

S3: setting the relation between the energy E of the γ photons and the energy channel number i as E=a+b×I, determining fit parameters a and b of an anode terminal count sequence Count_a and a cathode terminal count sequence Count_b respectively by utilizing two known energy spectral lines, for example, 1.17 MeV spectral line and 1.33 MeV spectral line of the γ ray of a 60Co radiation source and a 622 keV spectral line of a 137Cs radiation source, and finally obtaining a relation curve between the anode terminal count sequence Count_a and the energy E of the γ photons and a relation curve between the cathode terminal count sequence Count_c and the energy E of the γ photons.

S4: overlapping the Count_a(E) spectral line and the Count_c(E) spectral line to obtain a general detection spectral line Count (E).

The detection spectral line shown in FIG. 4 is calibrated by the above depth calibration method. The calibrated spectral line is as shown in FIG. 6. The detection curves generated by the two different incident depths (14) and (15) are (20) and (21) respectively. When the depth information is not calibrated, the general detection curve overlapped only according to the energy channel number is (22). If the detection curve is calibrated according to the depth information as a count value-γ photon energy curve, the general detection curve overlapped according to photon energy is (28). It can be seen from FIG. 6 that the half peak full width of the spectral line of the detection curve not calibrated is (26), and the half peak full width of the spectral line calibrated by the depth position information is (29). As the half peak full width (29) is smaller than the half peak full width (26), calibration of the depth position information can improve the energy resolution of γ photon detection.

The present invention has the following beneficial effects:
In the present invention, the p-i-n junction of perovskite is prepared by utilizing a solution doping epitaxial method; as the lattice structures in the junction interfaces are matched and small in defect density, compared with a heterojunction of perovskite prepared by methods such as spin-coating, the detector structure not only maintains the high absorption efficiency to the γ photons, but also inhibits the detection dark current and noise through a potential barrier of a depletion layer of the p-i-n junction;
a depth calibration algorithm is provided, which obtains the interaction depth position information of the γ photons by measuring the detection currents at the anode terminal and the cathode terminal respectively and calibrating the photon count sequence through the depth position, thereby improving the energy resolution of γ ray detection; and
the problem that the energy resolution is reduced as the interaction depths are different when the γ ray is incident at different angles is overcome, so that the effective working area of the detector can be increased, thereby not only maintaining a relatively high detection energy resolution, but also improving the external quantum efficiency of the detection.

### BRIEF DESCRIPTION OF THE DRAWINGS

FIGS. 1A-1C show a pixelated γ ray CZT detector structure.

FIG. 1A is an anode top view.

FIG. 1B is a cathode top view.

FIG. 1C is an anode picture penetrating through a substrate.

FIGS. 2A and 2B show a high resolution perovskite γ ray energy spectrometer.

FIG. 2A is a cathode surface top view.

FIG. 2B is a sectional view.

FIG. 3 shows generation and transportation of photo-induced carriers of a γ ray incident at different angles.

FIG. 4 is a detection energy spectrum formed by the γ ray at different incident depths.

FIG. 5 is a γ ray energy spectrum detector structure calibrated by the incident depth.

FIG. 6 is a detection spectral line after depth position calibration.

FIG. 7 is a γ ray detector structure based on a p-i-n junction of perovskite provided by the present invention.

FIG. 8 is a γ ray energy spectrum detection method calibrated by the incident depth.

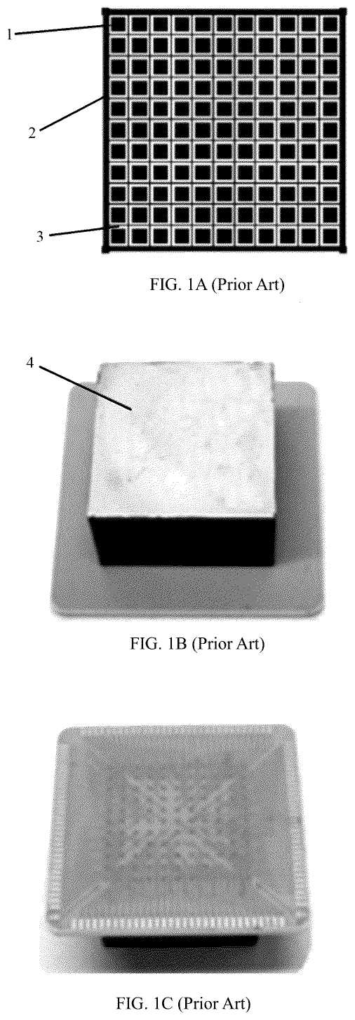

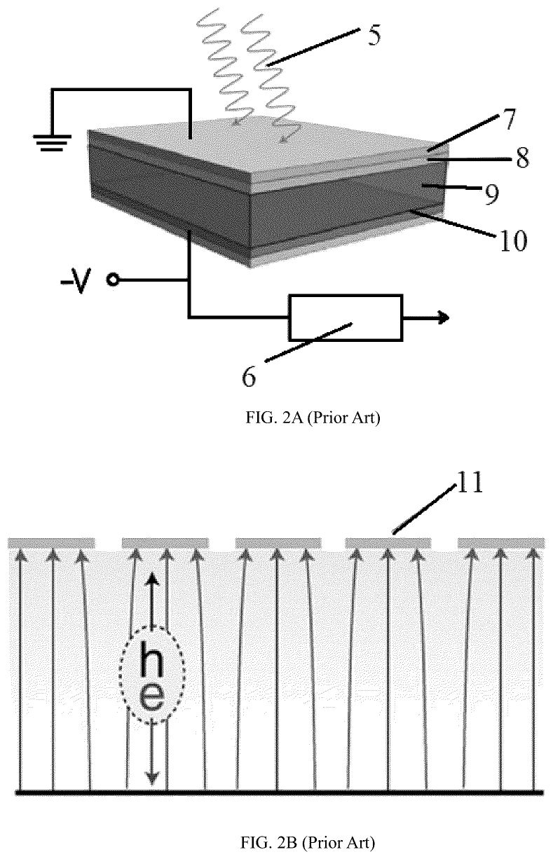

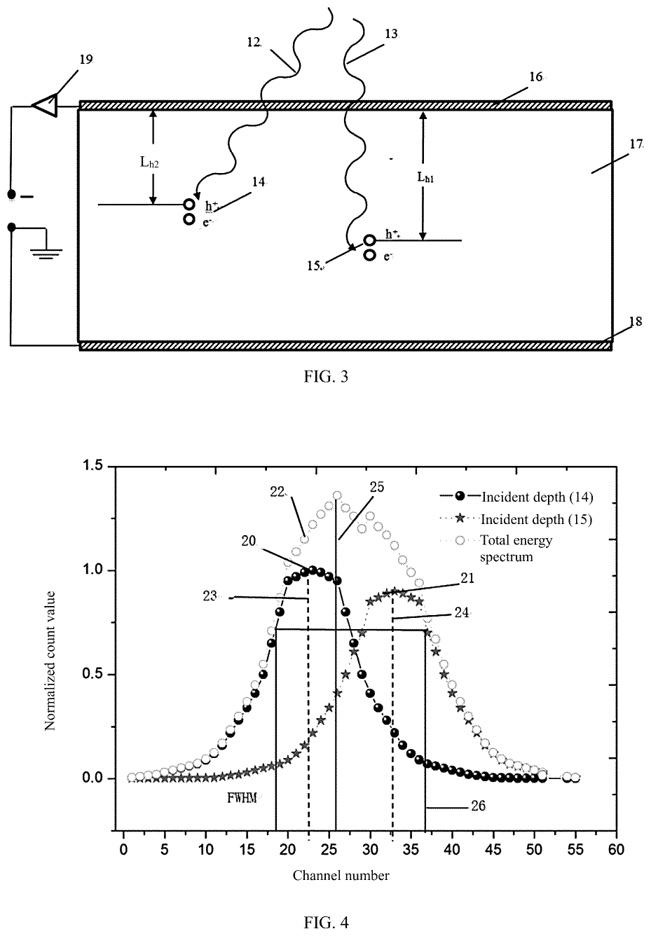

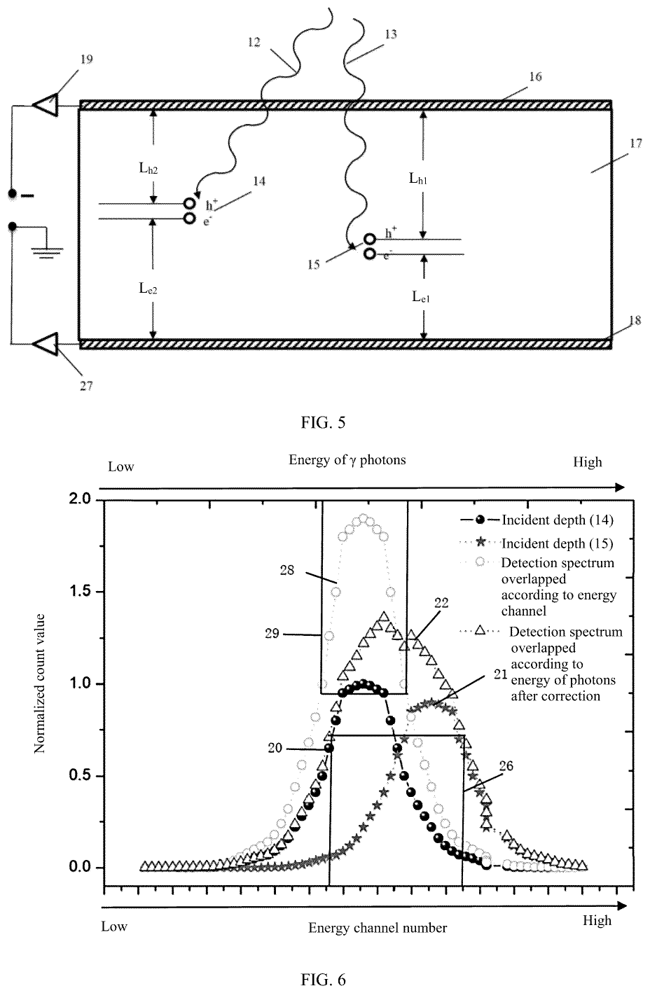

Numerals in drawings: 1—pixelated anode; 2—common grid; 3—insulating ring belt; 4—common cathode; 5—γ ray incidence; 6—preposed sensitive charge amplifier; 7—cathode electrode; 8—electron transmission layer; 9—perovskite crystal; 10—hole transmission layer; 11—pixelated anode; 12—γ ray incident at angle 1; 13—γ ray incident at angle 2; 14—electron-hole pairs generated by γ ray (12); 15—electron-hole pairs generated by γ ray (13); 16—anode; 17—photon conversion active body; 18—cathode; 19—anode sensitive charge amplifier; 20—detection spectral line obtained at the incident depth Lₕ₁ of γ ray; 21—detection spectral line obtained at the incident depth Lₕ₂ of γ ray; 22—detection spectral line synthesized by two incident depths; 23—peak energy channel at the incident depth Lₕ₁ of γ ray; 24—peak energy channel at the incident depth Lₕ₂ of γ ray; 25—peak energy channel of synthesized detection spectral line; 26—half peak full width of synthesized detection spectral line; 27—cathode sensitive charge amplifier; 28—general detection spectral line obtained according to overlap of energy of γ photons after depth position calibration; 29—half peak full width of detection spectral line (28); 30—γ ray incidence; 31—anode electrode; 32—p-type perovskite epitaxial layer; 33—perovskite intrinsic absorption layer; 34—n-type perovskite epitaxial layer; 35—cathode electrode; 36—voltage pulse at input terminal of sensitive charge amplifier; 37—current (charge) pulse at output terminal of sensitive charge amplifier.

### DETAILED DESCRIPTION OF THE EMBODIMENTS

In order to make technical means, creative features, objectives to achieve and efficacies implemented by the present invention be easily understood, the present invention will be further illustrated below in combination with specific embodiments and drawings. But the embodiments below are merely preferred embodiments of the present invention rather than all of the embodiments. On a basis of the embodiments in the implementation mode, all other embodiments obtained by those skilled in the art without making creative efforts fall into the scope of protection of the present invention.

Specific embodiments of the present invention are described below in combination of drawings.

### Embodiment 1

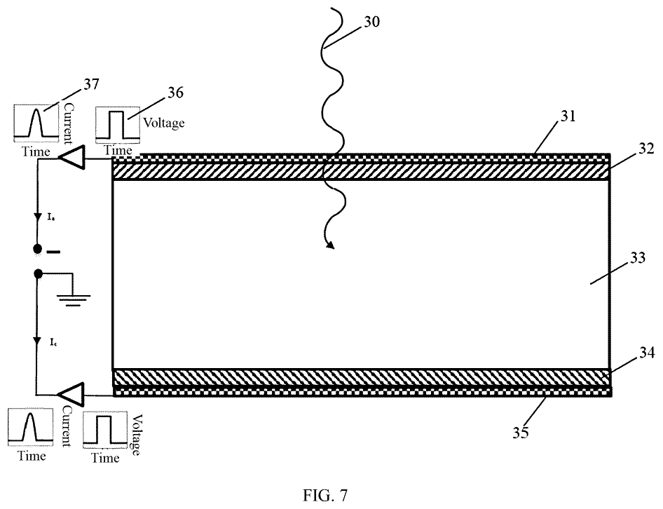

As shown in FIG. 7, an intrinsic perovskite crystal 33 with the thickness over 1 cm grows first by an inverse temperature method, for example MAPbBr_{2.5} Cl_{0.5} and the like. The intrinsic perovskite crystal is used as a γ ray photon absorption layer. A p-type perovskite epitaxial layer 32, for example, Ag⁺ doped MAPbBr₃, is prepared on an upper end surface of the intrinsic perovskite crystal 33 by way of solution epitaxial doping. An n-type perovskite epitaxial layer 34, for example, Bi³⁺ doped MAPbBr₃, is prepared on a lower end surface of the intrinsic perovskite crystal 33 by way of solution epitaxial doping. An anode electrode 31, for example, an Au electrode, is vacuum-evaporated at the upper end of the p-type perovskite epitaxial layer 32. A cathode electrode 35, for example, an Au electrode, is vacuum-evaporated at the lower end of the n-type perovskite epitaxial layer 34. A negative voltage is applied to the anode 31, and the cathode 35 is grounded to form reverser bias voltage setting of the p-i-n junction of the perovskite.

Sensitive charge amplifiers are arranged at the anode terminal and the cathode terminal, respectively to detect an anode current Ia and a cathode current Ic. In order to obtain the detection current effectively, a pulse voltage 36 is arranged at the front end of each sensitive charge amplifier, wherein the pulse time width is smaller than d/(μE), d is the thickness of the intrinsic perovskite crystal, g is the carrier mobility, E is the average electric field intensity, and the period of the front end pulse voltage is longer than the service life t of the carriers.

### Embodiment 2

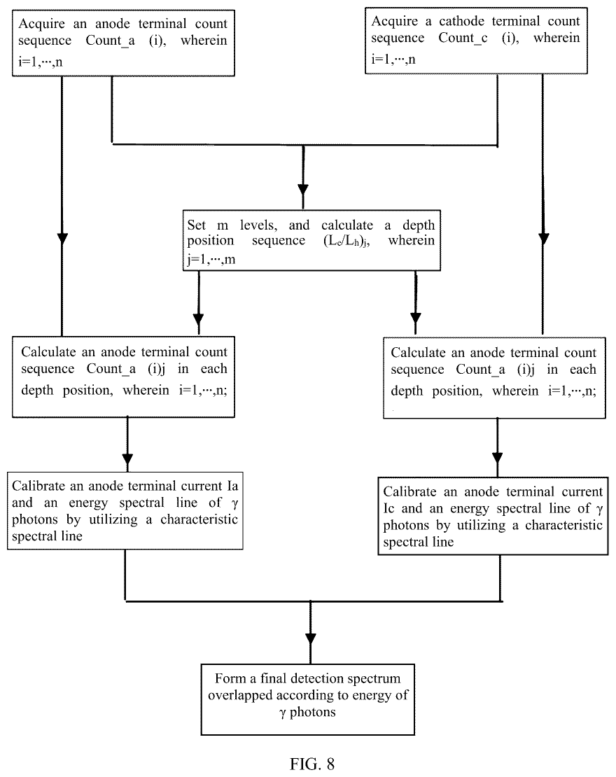

As shown in FIG. 8, according to the γ ray detector structure based on a p-i-n junction of perovskite and a calibration method, the depth position calibration method thereof includes: an anode terminal count value Count_a(i) and a cathode terminal count value Count_c(i) of each energy channel i are acquired first by way of conventional photon counting, wherein i is the energy channel number, and then the depth position information (Lₑ/Lₕ)=Count_a(i)/Count_c(i) is calculated thereby, the depth position is divided into m levels, and further, an anode terminal count sequence Count_a(i)j and a cathode terminal count sequence Count_c(i)j in each depth position are calculated according to a proximity principle of the depth position information (Le/Lₕ), wherein i=1, . . . , n; j=1, . . . , m; and further, an anode terminal current Ia, a cathode terminal current Ic and an energy spectral line of the γ photons are calibrated by utilizing a characteristic spectral line, and finally, a final detection spectral line is formed according to overlap of energy of the γ photons.

As the present invention uses the p-i-n detector structure of perovskite with matched lattice structure and the depth position calibration algorithm, dark current and noise are inhibited, and the detection energy resolution is improved. Moreover, the effective detection area can further be increased, and the detection quantum efficiency is improved.

In the present invention, unless otherwise specified and defined, the first feature is “above” or “below” the second feature, which may either include direct contact of the first feature and the second feature or include indirect contact of the first feature and the second feature but contact through other features therebetween. Moreover, the first feature is “on”, “above” and “over” the second feature, which includes that the first feature is right above and obliquely above the second feature or merely indicates that the horizontal height of the first feature is higher than that of the second feature. The first feature is “under”, “below” and “underneath” the second feature, which includes that the first feature is right below and obliquely below the second feature or merely indicates that the horizontal height of the first feature is lower than that of the second feature.

The basic principle, main features and advantages of the present invention are shown and described above. Those skilled in the art shall understand that the present invention is not subject to limitation of the above-mentioned embodiments. The above-mentioned embodiments and description merely describe the preferred embodiments of the present invention and are not used for limiting the present invention. There will be various variations and improvements of the present invention without departing from the spirit and scope of the present invention, and these variations and improvements shall fall into the claimed scope of the present invention. Therefore, the claimed protection scope of the present invention shall be defined by the appended claims and equivalents thereof.

What is claimed is:

1. A γ ray detector structure based on a p-i-n junction of perovskite,
wherein an ultrathick intrinsic perovskite crystal is used as a γ ray photon absorber;
a p-type layer and a n-type layer grow epitaxially at two ends of the ultrathick intrinsic perovskite crystal by solution doping to form the p-i-n junction, and a dark current and noise are detected by inhibition of a depletion layer in a junction area; and
energy spectrum distribution at different γ photon interaction depths is obtained by using a depth position calibration method, calibration parameters are determined by utilizing known characteristic peaks, and a γ ray detection energy resolution is improved by a depth position calibration algorithm.

2. The γ ray detector structure based on the p-i-n junction of perovskite according to claim 1, wherein a p-type epitaxial layer of the ultrathick intrinsic perovskite crystal is arranged at an upper end of the ultrathick intrinsic perovskite crystal thicker than 1 cm, an anode electrode is arranged at an upper end of the p-type epitaxial layer, an n-type epitaxial layer of the ultrathick intrinsic perovskite crystal is arranged at a lower end of the ultrathick intrinsic perovskite crystal, a cathode electrode is arranged at a lower end of the n-type epitaxial layer, and sensitive load amplifiers are arranged at an anode terminal and a cathode terminal respectively to form a perovskite detector.

3. The γ ray detector structure based on the p-i-n junction of perovskite according to claim 2, wherein a pulse time width of a reverse bias pulse voltage applied by the perovskite detector is smaller than d/(μE), wherein d is a thickness of the ultrathick intrinsic perovskite crystal, μ is a carrier mobility, E is an average electric field intensity, and a period of the reverse bias pulse voltage is longer than a service life τ of carriers.

4. A method for calibration of the γ ray detector structure based on the p-i-n junction of perovskite according to claim 1, comprising the following steps:
1) measuring a first detected signal at an anode terminal and a second detected signal at a cathode terminal simultaneously, and calibrating longitudinal interaction depths of γ photons according to a ratio of the first detected signal and the second detected signal;
2) classifying and counting detection events at a same depth respectively, and
determining the calibration parameters by utilizing the known characteristic peaks; and
3) obtaining a total detection energy spectrum curve according to a photon energy superposition method.

5. The method according to claim 4, wherein in the γ ray detector structure based on the p-i-n junction of perovskite, a p-type epitaxial layer of the ultrathick intrinsic perovskite crystal is arranged at an upper end of the ultrathick intrinsic perovskite crystal thicker than 1 cm, an anode electrode is arranged at an upper end of the p-type epitaxial layer, an n-type epitaxial layer of the ultrathick intrinsic perovskite crystal is arranged at a lower end of the ultrathick intrinsic perovskite crystal, a cathode electrode is arranged at a lower end of the n-type epitaxial layer, and sensitive load amplifiers are arranged at the anode terminal and the cathode terminal respectively to form a perovskite detector.

6. The method according to claim 5, wherein in the γ ray detector structure based on the p-i-n junction of perovskite, a pulse time width of a reverse bias pulse voltage applied by the perovskite detector is smaller than d/(μE), wherein d is a thickness of the ultrathick intrinsic perovskite crystal, μ is a carrier mobility, E is an average electric field intensity, and a period of the reverse bias pulse voltage is longer than a service life τ of carriers.
